(19) United States
(12) Patent Application Publication
(10) Pub. No.: US 2006/0244825 A1
(43) Pub. Date: Nov. 2, 2006

(54) Multi-function communication and navigation system and method for using the same

(76) Inventors: Bily Wang, Hsin Chu City (TW); Yuan-Hsiu Yang, Kaohsiung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/411,756

(22) Filed: Apr. 27, 2006

(30) Foreign Application Priority Data
Apr. 29, 2005 (TW) 94114028

(51) Int. Cl. H04N 7/18; H05K 11/00; H04M 1/00

(52) U.S. Cl. 348/115; 455/556.2; 455/344

(57) ABSTRACT

A multi-function communication and navigation system includes a GPS and MCU module, a memory module, a sensor module, a power module, a HUD module, an audio input/output module and a Bluetooth module. The system can be a recorder for recording relevant mobile information in the memory module. The HUD module can project relevant information such as velocity, direction, time, date etc. onto a display area. Moreover, the communication message can be transformed into audible sounds for broadcasting, so that the system can be a wireless intercom device for communicating with other systems. Moreover, when a sensor module of the system receives a vibrating message such as a collision message, the system can automatically dial an emergency number and provide relevant location information via the Bluetooth module.

### BACKGROUND OF THE INVENTION

1. Field of the Invention

The present invention relates to a multi-function communication and navigation system and method for using the same, and particularly relates to a multi-function communication and navigation system having a Head-Up Display (HUD) module, a Bluetooth module, and a GPS receiver integrated together.

2. Description of the Related Art

With the improvement of technology and a decrease in the costs of production, navigation systems are moving away from the original military use. These days they are finding more civilian applications, for example, most new cars are now outfitted with a navigation system when they are manufactured. The purpose of a navigation system is to display a map showing the car's current location, and guiding drivers smoothly to their destination.

Although GPS (Global Position System) was originally developed by the USA government, it is now accessible to the public. GPS provides precise location and time information. GPS is composed of more than 20 satellites and several ground control stations. Users can immediately calculate their location, speed and time via a GPS receiver that continuously tracks and receives signals from the satellites.

However, a conventional GPS receiver does not provide more functions beyond receiving information from the satellites and outputting information to users.

### SUMMARY OF THE INVENTION

The present invention provides a multi-function communication and navigation system and method for using the same. The multi-function communication and navigation system provides a GPS and MCU module for receiving and decoding relevant information, and then records the information in a memory module. The system also provides a HUD module for projecting the relevant information such as velocity, direction, time, date etc. onto a display area. The system further provides warning information for a user so that they know the whereabouts of speed cameras, filling stations, convenience stores, toll stations, rest stations, or scenic spots.

Furthermore, the system provides a Bluetooth module for receiving communication messages. Communication messages can be transformed into audible sounds for broadcasting, so that the system can be a wireless intercom device for communicating with other systems. Moreover, relevant information or communication messages can be transmitted to another system via the Bluetooth module. Moreover, when a sensor module of the system receives a vibrating message such as a collision message, the system can automatically dial an emergency number and provide relevant location information via the Bluetooth module.

The first aspect of the invention is a multi-function communication and navigation system. The multi-function communication and navigation system includes a GPS and Micro Control Unit (MCU) module, a memory module, a sensor module, a power module, a Head-Up Display (HUD) module, an audio input/output module and a Bluetooth module. The GPS and Micro Control Unit (MCU) module has a GPS receiver for receiving satellite signals and a MCU. The memory module electrically connects with the GPS and MCU module for recording and storing data. The sensor module electrically connects with the GPS and MCU module for providing signals to the MCU. The power module electrically connects with the GPS and MCU module to provide power to the communication and navigation system. The Head-Up Display (HUD) module electrically connects with the GPS and MCU module to project and display information. The audio input/output module electrically connects with the GPS and MCU module for outputting and inputting audio signals, and the Bluetooth module electrically connects with the GPS and MCU module for providing a wireless communication function and a wireless transmission function.

The second aspect of the invention is a method for using a multi-function communication and navigation system. The method includes receiving action information via a GPS and Micro Control Unit (MCU) module, receiving the action information via a Head-Up Display (HUD) module, and projecting the action information onto a display area via the HUD module.

The third aspect of the invention is a method for using a multi-function communication and navigation system. The method includes receiving action information via a GPS and Micro Control Unit (MCU) module, producing warning information by comparing the action information with database information that is predeterminedly stored in a memory module, and projecting the warning information onto a display area via a HUD module.

The fourth aspect of the invention is a method for using a multi-function communication and navigation system. The method includes receiving a communication message via a Bluetooth phone, receiving the communication message via a Bluetooth module by a wireless method, transmitting the communication message to an audio input/output module via a GPS and Micro Control Unit (MCU) module, and transforming the communication message into audible sounds for broadcasting via the audio input/output module. Moreover, following the step of receiving the communication message, the method further includes transmitting the communication message to a Head-Up Display (HU) module via the GPS and MCU module, and projecting the communication message with caller ID onto a display area via the HUD module.

The fifth aspect of the invention is a method for using a multi-function communication and navigation system. The method includes receiving a vibrating message via a sensor module, transmitting the vibrating message to a Bluetooth module via a GPS and Micro Control Unit (MCU) module, and automatically dialing at least one predetermined telephone number via the Bluetooth module.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1 is a function block diagram of a multi-function communication and navigation system according to the present invention;

FIG. 2 is an application, schematic diagram of a multi-function communication and navigation system according to the present invention;

FIG. 3 is a flowchart of a method for using a multi-function communication and navigation system according to the first embodiment of the present invention;

FIG. 4 is a flowchart of a method for using a multi-function communication and navigation system according to the second embodiment of the present invention;

FIG. 5 is a flowchart of a method for using a multi-function communication and navigation system according to the third embodiment of the present invention; and

FIG. 6 is a flowchart of a method for using a multi-function communication and navigation system according to the fourth embodiment of the present invention.

### DETAILED DESCRIPTION OF PREFERRED EMBODIMENTS

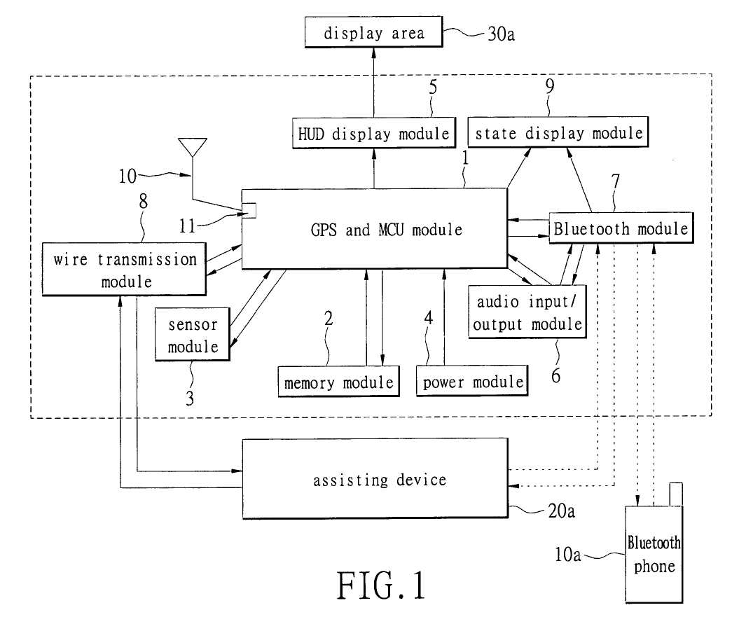

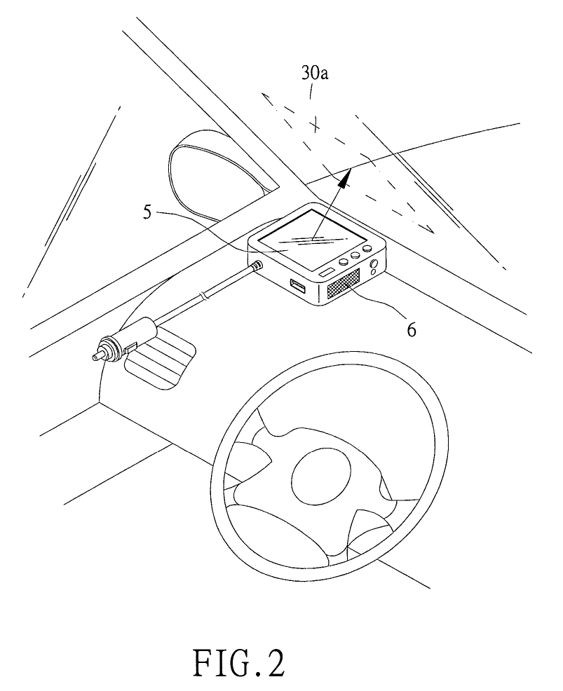

FIGS. 1 and 2 are, respectively, a function block diagram and an application, schematic diagram of a multi-function communication and navigation system according to the present invention. The multi-function communication and navigation system includes a GPS and Micro Control Unit (MCU) module 1, a memory module 2, a sensor module 3, a power module 4, a Head-Up Display (HUD) module 5, an audio input/output module 6 and a Bluetooth module 7.

The GPS and MCU module is composed of a GPS receiver for receiving satellite signals and a MCU. The GPS and MCU module further has an external antenna 10 and a built-in antenna 11. The memory module 2 electrically connects with the GPS and MCU module 1 for recording and storing data. The memory module 2 can be a Non-Volatile Random Access Memory (NVRAM).

Moreover, the sensor module 3 electrically connects with the GPS and MCU module 1 for providing signals to the MCU. The sensor module 3 can be an adjustable sensitivity sensor. Hence, a user can adjust the sensitivity of the sensor module 3 according to needs of the user. The power module 4 electrically connects with the GPS and MCU module 1 for providing power to the communication and navigation system. The power module 4 has a built-in rechargeable battery and/or an external plug for providing the user different power supply methods. For example, the user can use the built-in rechargeable battery when driving a short distance, or use the external plug to plug into a power socket of a car when driving long distances.

Furthermore, the HUD module 5 electrically connects with the GPS and MCU module 1 for projecting and displaying information. The HUD module 5 has an LED array for projecting information by a dot matrix method. The audio input/output module 6 electrically connects with the GPS and MCU module 1 for outputting and inputting audio signals. The audio input/output module 6 is a loudspeaker/microphone module, and has a loudspeaker for outputting audio and a microphone for inputting audio.

Furthermore, the Bluetooth module 7 electrically connects with the GPS and MCU module 1 for providing a wireless communication function and a wireless transmission function. The Bluetooth module 7 is wirelessly connected with an assisting device 20a or a Bluetooth phone 10a. In addition, the multi-function communication and navigation system further includes a wire transmission module 8 electrically connected with the GPS and MCU module 1 for providing a wire transmission function, and a state display module 9 at least electrically connected with the GPS and MCU module 1 and the Bluetooth module 7 for displaying the usage state of each of the modules, such as whether they are turned on or off.

The wire transmission module 8 electrically connects with an assisting device 20a via a transmission wire. The assisting device 20a can be a handheld device or a portable PC, and the handheld device can be a PDA (Personal Digital Assistant) and the portable PC can be a notebook.

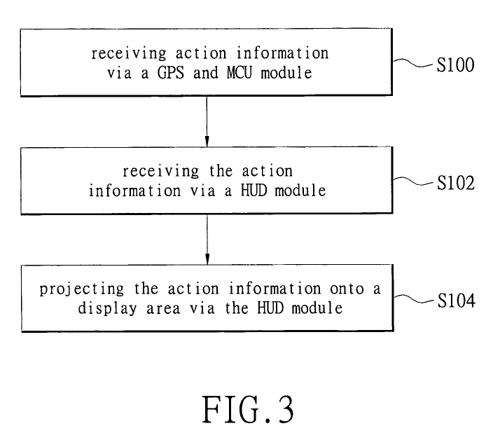

FIG. 3 shows a flowchart of a method for using a multi-function communication and navigation system according to the first embodiment of the present invention. The first embodiment of the present invention provides a method for using a multi-function communication and navigation system. The method includes receiving action information via a GPS and Micro Control Unit (MCU) module 1 (S100), receiving the action information via a Head-Up Display (HUD) module 5 (S102), and projecting the action information onto a display area 30a via the HUD module 5 (S104). Moreover, the action information can be mobile information with a current speed and a current position, or mobile information with a correct time and a correct date. The mobile information with the correct time and the correct date is used to update a clock. Moreover, the action information can be recorded in a memory module 2, and can be transmitted to an assisting device 20a via a Bluetooth module 7 and a wire transmission module 8.

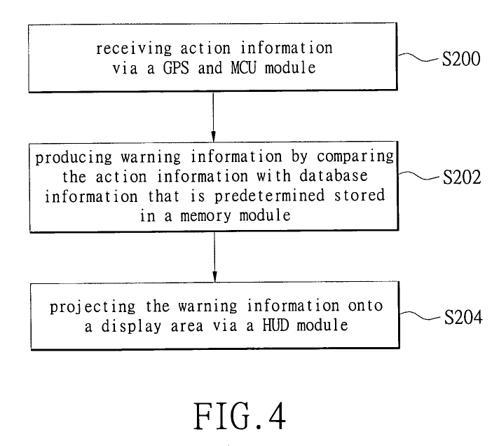

FIG. 4 shows a flowchart of a method for using a multi-function communication and navigation system according to the second embodiment of the present invention. The second embodiment of the present invention provides a method for using a multi-function communication and navigation system. The method includes receiving action information via a GPS and Micro Control Unit (MCU) module 1 (S200), producing warning information via comparing the action information with database information that is predetermined stored in a memory module 2 (S202), and projecting the warning information onto a display area 30a via a HUD module 5 (S204).

Moreover, the action information can be mobile information with a current speed and a current position, and the database information is the current location's speed limit information. The mobile information compares with the speed limit information to send out the warning information with a speed limit so that the user can judge whether their current speed exceeds a speed limit of the speed limit information or not. Furthermore, the action information can be mobile information with a current position, and the database information is particular position information. The mobile information with the current position is compared with the particular position information to send out warning information for user to know that where is a particular position, how the distance from the current position to the particular position, and note information regarding the particular position. The particular position can provide information such as, but not limited to, the location of speed camera areas, filling stations, convenience stores, toll stations, rest stations, and scenic spots.

In addition, the action information can be recorded in a memory module 2, and the action information stored in the memory module 2 can be transmitted to an assisting device 20a as mobile records or navigation information via a Bluetooth module 7 and a wire transmission module 8.

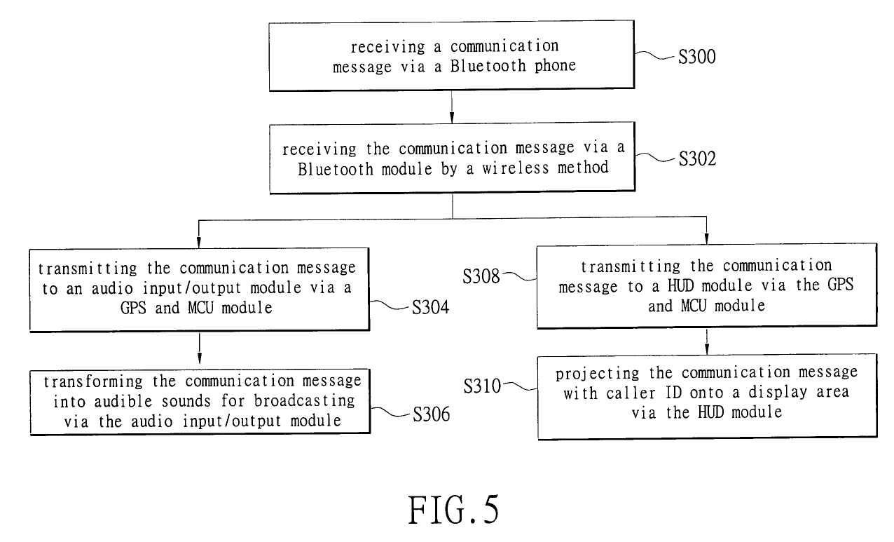

FIG. 5 shows a flowchart of a method for using a multi-function communication and navigation system according to the third embodiment of the present invention. The third embodiment of the present invention provides a method for using a multi-function communication and navigation system. The method includes receiving a communication message via a Bluetooth phone 10a (S300), receiving the communication message via a Bluetooth module 7 by a wireless method (S302), transmitting the communication message to an audio input/output module 6 via a GPS and Micro Control Unit (MCU) module 1 (S304), and transforming the communication message into audible sounds for broadcasting via the audio input/output module 6 (S306). Moreover, the audio input/output module 6 can be a wireless intercom device for communicating with other multi-function communication and navigation systems (not shown) with another audio input/output module.

Furthermore, after the step S302, the method further includes transmitting the communication message to a Head-Up Display (HUD) module 5 via the GPS and MCU module 1 (S308), and projecting the communication message with caller ID onto a display area 30a via the HUD module 5 (S310). The caller ID at least includes a name, a phone number or a relationship note such as family, friend or customer.

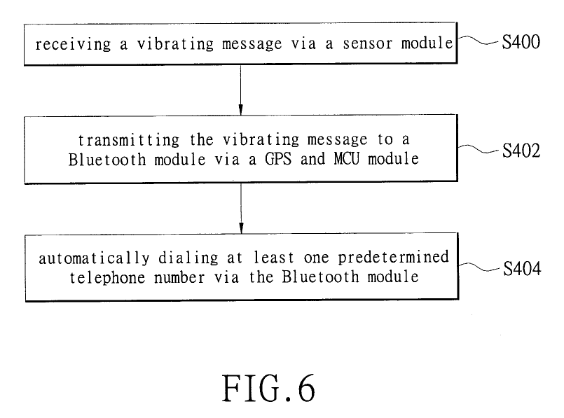

FIG. 6 shows a flowchart of a method for using a multi-function communication and navigation system according to the fourth embodiment of the present invention. The fourth embodiment of the present invention provides a method for using a multi-function communication and navigation system. The method includes receiving a vibrating message via a sensor module 3 (S400), transmitting the vibrating message to a Bluetooth module 7 via a GPS and Micro Control Unit (MCU) module 1 (S402), and automatically dialing at least one predetermined telephone number via the Bluetooth module 7 (S404). Moreover, the sensor module 3 can be an adjustable sensitivity sensor, and the at least one predetermined telephone number can be an emergency number (for example 119 or 110 in Taiwan), a local number, or a cell phone number according to needs of the user.

In conclusion, the multi-function communication and navigation system can be a recorder for recording relevant mobile information in the memory module. The HUD module can project relevant information such as velocity, direction, time, date etc. onto a display area. Moreover, the communication message can be transformed into audible sounds for broadcasting, so that the system can be a wireless intercom device for communicating with other systems. Moreover, when a sensor module of the system receives a vibrating message such as a collision message, the system can automatically dial an emergency number and provide relevant location information via the Bluetooth module.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A multi-function communication and navigation system, comprising:
a GPS and Micro Control Unit (MCU) module having a GPS receiver for receiving satellite signals, and a MCU;
a memory module electrically connecting with the GPS and MCU module, for recording and storing data;
a sensor module electrically connecting with the GPS and MCU module, for providing signals to the MCU;
a power module electrically connecting with the GPS and MCU module, for providing power to the communication and navigation system;
a Head-Up Display (HUD) module electrically connecting with the GPS and MCU module, for projecting and displaying information;
an audio input/output module electrically connecting with the GPS and MCU module, for outputting and inputting audio signals; and
a Bluetooth module electrically connecting with the GPS and MCU module, for providing a wireless communication function and a wireless transmission function.

2. The system as claimed in claim 1, wherein the GPS and MCU module has a built-in antenna.

3. The system as claimed in claim 1, wherein the GPS and MCU module has an external antenna.

4. The system as claimed in claim 1, wherein the memory module is a Non-Volatile Random Access Memory (NVRAM).

5. The system as claimed in claim 1, wherein the sensor module is an adjustable sensitivity sensor.

6. The system as claimed in claim 1, wherein the power module has a built-in rechargeable battery.

7. The system as claimed in claim 1, wherein the power module has an external plug.

8. The system as claimed in claim 1, wherein the HUD module has an LED array for projecting information by a dot matrix method.

9. The system as claimed in claim 1, wherein the audio input/output module has a loudspeaker for outputting audio and a microphone for inputting audio.

10. The system as claimed in claim 1, wherein the Bluetooth module is wirelessly connected with an assisting device.

11. The system as claimed in claim 1, wherein the Bluetooth module is wirelessly connected with a Bluetooth phone.

12. The system as claimed in claim 1, further comprising a wire transmission module electrically connecting with the GPS and MCU module for providing wire transmission function.

13. The system as claimed in claim 12, wherein the wire transmission module electrically connects with an assisting device.

14. The system as claimed in claim 12, wherein the wire transmission module electrically connects with an assisting device via a transmission wire.

15. The system as claimed in claim 10, wherein the assisting device is a handheld device or a portable PC.

16. The system as claimed in claim 15, wherein the handheld device is a PDA, and the portable PC is a notebook.

17. A method for using a multi-function communication and navigation system, comprising:
receiving action information via a GPS and Micro Control Unit (MCU) module;
receiving the action information via a Head-Up Display (HUD) module; and
projecting the action information onto a display area via the HUD module.

18. The method as claimed in claim 17, wherein the action information is mobile information comprising a current speed and a current position.

19. The method as claimed in claim 17, wherein the action information is mobile information comprising a correct time and a correct date.

20. The method as claimed in claim 19, wherein the mobile information with the correct time and the correct date is used to update a clock.

21. The method as claimed in claim 17, wherein the action information is recorded in a memory module.

22. The method as claimed in claim 17, wherein the action information is transmitted to an assisting device via a Bluetooth module and a wire transmission module.

23. A method for using a multi-function communication and navigation system, comprising:
receiving action information via a GPS and Micro Control Unit (MCU) module;
producing warning information by comparing the action information with database information which is predeterminedly stored in a memory module; and
projecting the warning information onto a display area via a HUD module.

24. The method as claimed in claim 23, wherein the action information is mobile information comprising a current speed and a current position, and the database information is speed limit information, wherein the mobile information is compared with the speed limit information for sending out the warning information with a speed limit to user to judge whether the current speed exceeds a speed limit of the speed limit information or not.

25. The method as claimed in claim 23, wherein the action information is mobile information comprising a current position, and the database information is particular position information, wherein the mobile information with the current position is compared with the particular position information to send out warning information for user to know that where is a particular position, how the distance from the current position to the particular position, and note information regarding the particular position.

26. The method as claimed in claim 23, wherein the particular position comprises locations of speed cameras, filling stations, convenience stores, toll stations, rest stations, or scenic spots.

27. The method as claimed in claim 23, wherein the action information is recorded in a memory module.

28. The method as claimed in claim 23, wherein the action information is transmitted to an assisting device as mobile records or navigation information via a Bluetooth module and a wire transmission module.

29. A method for using a multi-function communication and navigation system, comprising:
receiving a communication message via a Bluetooth phone;
receiving the communication message via a Bluetooth module by a wireless method;
transmitting the communication message to an audio input/output module via a GPS and Micro Control Unit (MCU) module; and
transforming the communication message into sounds for broadcasting via the audio input/output module.

30. The method as claimed in claim 29, wherein the audio input/output module is a wireless intercom device for communicating with other multi-function communication and navigation systems with other audio input/output modules.

31. The method as claimed in claim 29, wherein after receiving the communication message, the method further comprises:
transmitting the communication message to a Head-Up Display (HUD) module via the GPS and MCU module; and
projecting the communication message with caller ID onto a display area via the HUD module.

32. A method for using a multi-function communication and navigation system, comprising:
receiving a vibrating message via a sensor module;
transmitting the vibrating message to a Bluetooth module via a GPS and Micro Control Unit (MCU) module; and
automatically dialing at least one predetermined telephone number via the Bluetooth module.

33. The method as claimed in claim 32, wherein the sensor module is an adjustable sensitivity sensor.

34. The method as claimed in claim 32, wherein the at least one predetermined telephone number is an emergency number, a local number, or a cell number.
